(19) United States
(12) Patent Application Publication
(10) Pub. No.: US 2007/0026584 A1
(43) Pub. Date: Feb. 1, 2007

(54) Dielectric isolated body biasing of silicon on insulator

(75) Inventor: Andrew Marshall, Dallas, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/192,692

(22) Filed: Jul. 29, 2005

(51) Int. Cl. H01L 21/84

(52) U.S. Cl. 438/151

(57) ABSTRACT

The present invention provides, in one aspect, a microelectronics device 100 that includes a silicon on insulator (SOI) region 110 located over a microelectronics substrate 115. The SOI region 110 comprises a first dielectric layer 120 located over the microelectronics substrate 115, a biasing layer 125 located over the first dielectric layer 120, and a second dielectric layer 130 located over the biasing layer 125. An active region 135 is located over the SOI region 110. Contact plugs 140 extend through the active region 135 and within the SOI region 110. The present invention also includes a method for making the microelectronics device 100.

### TECHNICAL FIELD OF THE INVENTION

The present invention is directed in general to a microelectronics device, and more specifically, to a microelectronics device that has a body isolated between two buried dielectric layers that can be biased to reduce leakage of the microelectronics device in the off state.

### BACKGROUND

Optimization of integrated circuits is a hard sought after goal of the semiconductor manufacturing industry. Often, however, achieving optimization means balancing benefits and detriments of various processes and device designs. In one case, for example, a device might be configured with a body contact that allows a positive body bias to be placed on the device that provides an increased drive current, and thus faster switching speed during the “on” state, but this might occur at the cost of higher current leakage when the device is in the “off” state.

Conventional integrated circuits are typically fabricated on relatively thick wafers of monocrystalline bulk silicon. While only a thin top layer of the silicon, typically less than a micrometer in thickness is utilized by the circuit devices. Such wafers are utilized in the fabrication of integrated circuits using a variety of technologies, including CMOS, NMOS, bipolar and BiCMOS technologies.

Unfortunately, the underlying bulk silicon leads to a variety of adverse parasitic effects. Specifically, the underlying silicon contributes to the parasitic capacitance of each transistor and introduces parasitic capacitance into the device, which can affect switching speed to some degree. However, various techniques can be used to increase drive current, and thus switching speeds, and in devices fabricated on bulk silicon, for example 69 nm or less, one is still able to get an acceptable amount of device performance, even in view of the parasitic capacitance that exists at the source/drain junctions of the device. However, as device sizes continue to shrink, the parasitic capacitance may become more of a substantial problem.

To further optimize transistors, the industry has sought to reduce this parasitic capacitance by the introduction of a buried oxide layer, which is known as silicon on insulator (SOI), under the active region of the transistor gate. SOI has a much lower capacitance and various techniques can be used to get higher drive currents. These higher current drives, in view of the lower. capacitance, yield a device with better performance, since these devices work on current driving capacitances at different switching performance. Unfortunately, while faster switching speeds are achieved, depending on design,these devices suffer from a greater amount of leakage when the device is in the “off” state. To address this problem, the industry has provided surface body contacts to negatively bias the body of the device. However, these surface contacts have undesirable drawbacks. For example, certain types of SOI have a body region that may be depleted of carrier during part or all its operating range. A depleted region cannot be reliably connected electrically with a top surface contact.

Accordingly, what is needed in the art is a microelectronics device that overcomes the deficiencies discussed above.

### SUMMARY OF INVENTION

To address the above-discussed deficiencies of the prior art, the present invention provides, in one embodiment, a method of fabricating a microelectronics device. This embodiment comprises forming a silicon on insulator (SOI) region within a microelectronics substrate. The SOI region comprises a first dielectric layer located over the microelectronics substrate, a biasing layer located over the first dielectric layer and a second dielectric layer located over the biasing layer. The method further comprises forming an active region over the SOI region and locating a contact plug through the active region and within the SOI region. The contact plug electrically contacts the biasing layer of the SOI region and is electrically isolated from the active region.

In another embodiment, the present invention includes a method of fabricating an integrated circuit. In this embodiment, the method comprises forming a silicon on insulator (SOI) region within at least a portion of a microelectronics substrate. The SOI region comprises a first dielectric layer located over the microelectronics substrate, a biasing layer located over the first dielectric layer and a second dielectric layer located over the biasing layer. An active region is formed over the SOI region. The method further comprises creating transistors over the active region where each of the transistors is electrically isolated from the active region by a gate oxide, and locating biasing contact plugs through the active region and within the SOI region adjacent at least a portion of the transistors. The contact plugs electrically contact the biasing layer of the SOI region and is electrically isolated from the active region. The method further comprises depositing dielectric layers over the transistors and forming interconnects within the dielectric layers to interconnect the transistors and the biasing contact plugs to form an operative integrated circuit.

In another embodiment, the present invention provides a microelectronics device. The microelectronics device comprises a silicon on insulator (SOI) region located within a microelectronics substrate. The SOI region comprising a first dielectric layer located over the microelectronics substrate, a biasing layer located over the first dielectric layer and a second dielectric layer located over the biasing layer. The device further comprises an active region located over the SOI region and a contact plug located through the active region and within the SOI region. The contact plug electrically contacts the biasing layer of the SOI region and is electrically isolated from the active region.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a partial, sectional view of one embodiment of a microelectronics device as provided by the present invention;

FIG. 2A illustrates a partial, sectional view of a microelectronic substrate undergoing a first oxide region implant;

FIG. 2B illustrates a partial, sectional view of the microelectronics substrate of FIG. 2A undergoing a second oxide region implant;

FIG. 2C illustrates a partial, sectional view of the microelectronics substrate of FIG. 2B following a post anneal step;

FIG. 3A illustrates sectional views of an active wafer and a support wafer showing the optional oxidization of the upper surface;

FIG. 3B illustrates a sectional view of the active wafer after oxidization of the upper surface;

FIG. 3C illustrate a section view of a substrate structure after the active wafer and support wafer are bonded together;

FIG. 4 illustrates a partial sectional view of a microelectronic device following the formation of a SOI region therein;

FIG. 5A illustrates a partial sectional view of the microelectronics device of FIG. 4 after the formation of contact openings;

FIG. 5B illustrates a partial sectional view of the microelectronics device of FIG. 5A after the formation of isolation regions within the contact openings;

FIG. 5C illustrates a partial sectional view of an alternative embodiment of the device of FIG. 5B that includes a separate isolation structure; and

FIG. 6 illustrates a partial sectional view of a multi-layered integrated circuit that can be fabricated according to the principles of the present invention.

### DETAILED DESCRIPTION

The present invention recognizes the advantages associated with using a biasing body located between dielectric layers within an isolated SOI region in a microelectronics device. By way of a contact plug that extends into the SOI region, the biasing body can be negatively or positively biased to either increase drive current when the microelectronics device is in the “on” state or reduce current leakage when the microelectronics device is in the “off” state, or both if so desired. The way in which the device is biased to achieve the desired affect depends on the type of device (nmos or pmos) that the microelectronics device is. Thus by employing the principles of the present invention the operation of a transistor within an integrated circuit can be further optimized.

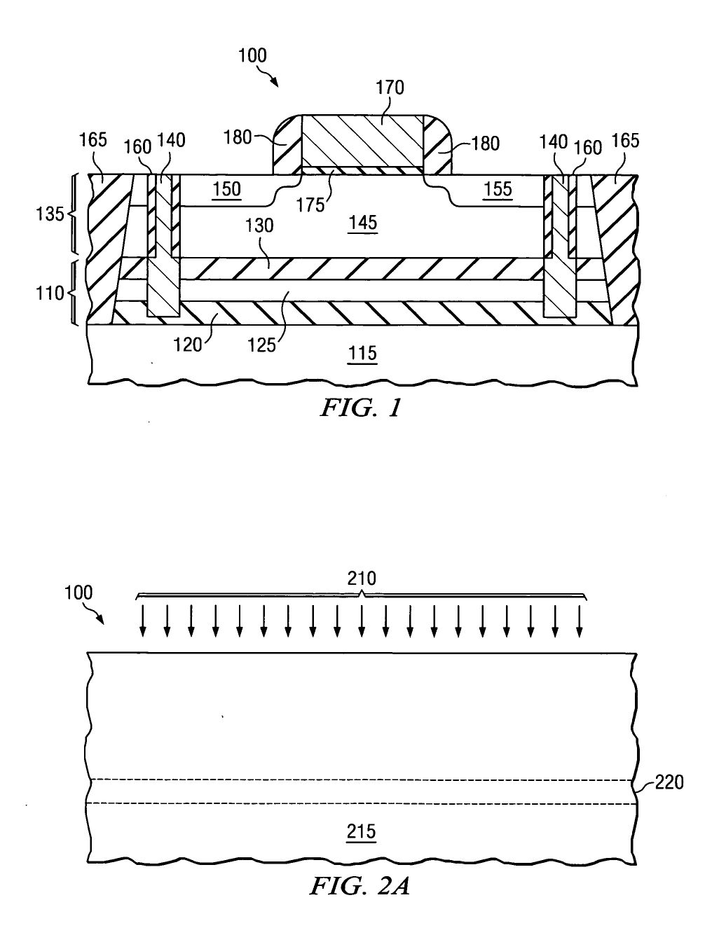

Turning initially to FIG. 1, there is generally illustrated a partial, sectional view of one embodiment of a microelectronics device 100 as provided by the present invention. This particular embodiment includes a silicon on insulator (SOI) region 110 located over a microelectronics substrate 115. The SOI region 110 comprises a first dielectric layer 120 located over the microelectronics substrate 115, a biasing layer 125 located over the first dielectric layer 120, and a second dielectric layer 130 located over the biasing layer 125. The first and second dielectric layers 120 and 130 may be formed with any type of dielectric material known to those skilled in the art, such as silicon dioxide or silicon nitride. An active region 135 is located over the SOI region 110. Contact plugs 140 extend through the active region 135 and within the SOI region 110. While two contact plugs are illustrated, in other embodiments, one is sufficient. The active region will typically include a well 145 and source/drains 150 and 155, respectively located within the well 145. The contact plugs 140 electrically contact the biasing layer 125 that is electrically isolated from the active region 135 by isolation structures 160.

The microelectronics device 100 further includes conventionally formed trench isolation structures 165, and a conventionally formed transistor gate 170, gate oxide 175 and spacers 180. In the illustrated embodiment, microelectronics device 100 is an NMOS device in which the biasing layer 125 and the source/drains 150, 155 are appropriately doped with an n-type dopant, and the microelectronics substrate 115 and the well 145 are appropriately doped with a p-type dopant. These doping schemes, of course, will be reversed in a PMOS device and one who is skilled in the art would understand how to dope the respective structures generally discussed above.

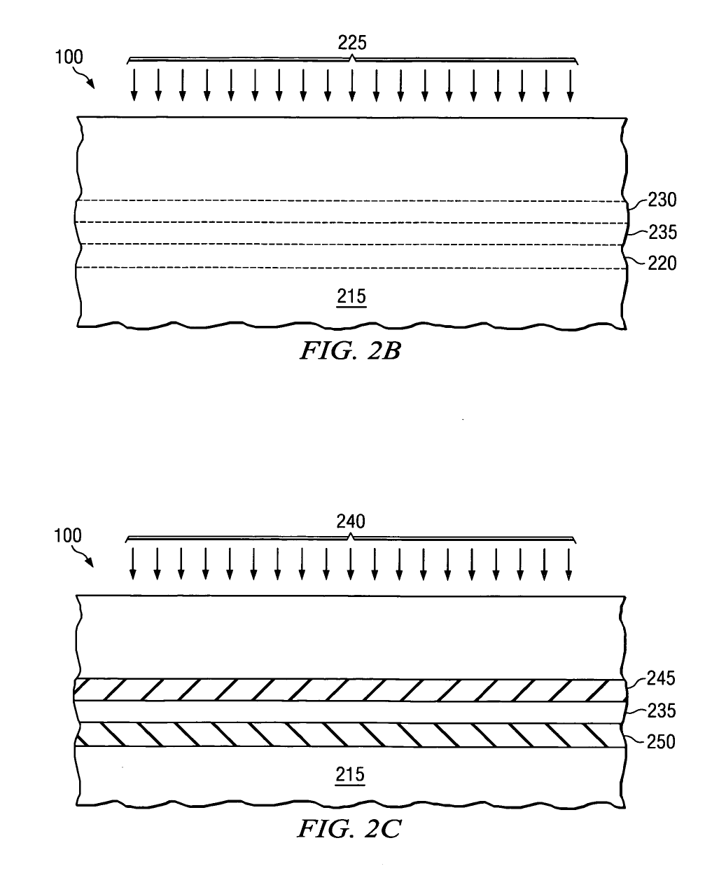

Turning now to FIGS. 2A-2C, there are illustrated method steps of one embodiment by which the SOI region 110 of the microelectronics device 100 of FIG. 1 can be formed. In on advantageous embodiment, as shown in FIG. 2A, oxygen is implanted (indicated by arrows 210) into the bulk doped substrate 215, using conventional processes, to form a first oxygen implanted region 220 within the substrate 215, indicated by the dashed lines. As mentioned above, other embodiments may include the use of those materials that were previously mentioned. The formation of the SOI may occur at the very initial stages of manufacture and before the formation of isolation regions or well regions, as illustrated in FIGS. 2A-2C. This embodiment is well suited to those instances where it is desirable to have multiple transistor devices configured with the SOI region. In alternative embodiments, the SOI region may be formed later and conventional lithographic techniques can be used to mask the desired portions of the substrate into which the SOI region can then be formed. This embodiment is well suited for those instances where it is desired to have only a portion of the transistor devices associated with the SOI region.

Shown in FIG. 2B is a step showing a second oxygen implant (indicated by arrows 225) that is conducted, using conventional processes, to form a second oxygen implanted region 230, also indicated by the dashed lines. The second oxygen implant is conducted in such a way to leave a bias region 235 between the first and second oxygen implanted regions 220 and 230. The thickness of the implanted regions 220, 230 and the biasing region 235 may vary, depending on the design parameters of the microelectronics device 100. For example, their thicknesses may range from about 0.5 microns to about 1 micron.

Following the implants as described above, an anneal (shown by the arrows 240) is then conducted to form dielectric layers 245 and 250, such as dioxide layers, as shown in FIG. 2C, with the bias region 235 located therebetween. The biasing region 235 can be formed by using conventional processes and appropriately doping the biasing region 235 with a dopant the same as or opposite to that used to dope the well and substrate, depending on the type of device, either before or after the formation of the second dioxide region 250. The processes used to conduct these implants and anneal are well known to those skilled in the art and it should be noted that they are typically used to form a single dielectric layer versus the two spaced apart dielectric layers as provided by the present invention.

For example, the above described oxygen implant process is known within the industry as a Separation by Implanted Oxygen (SIMOX) process and is just one process that can be used to form the dioxide regions 245 and 250. Also, it should be pointed out that while only two dielectric layers are shown and discussed, other embodiments might include more than two of these dielectric layers within the SOI region.

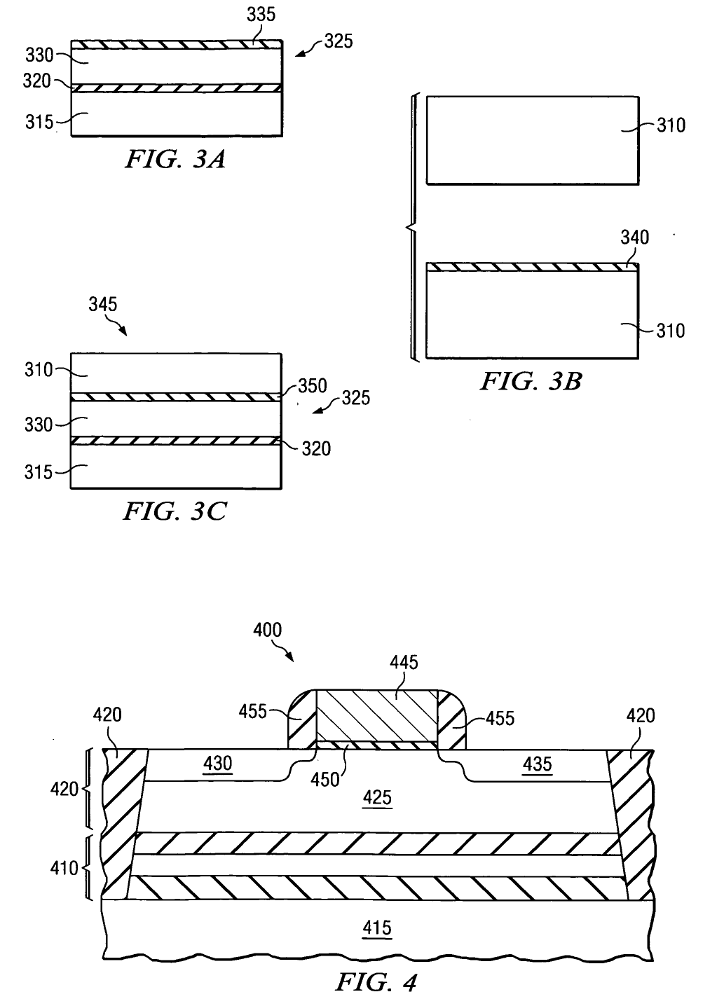

Turning now to FIGS. 3A through 3C, there is illustrated a method of another embodiment by which the SOI region of the microelectronics device 100 of FIG. 1 can be formed.

In this particular embodiment, FIG. 3A shows first and second microelectronics substrates 310 and 315, respectively. The first microelectronics substrate 310 may be referred to herein as the active wafer or donor wafer and the second microelectronics substrate 315 may be referred to as the support wafer or handle wafer. The microelectronics substrate 315 is implanted to form a first dielectric layer 320 as described above regarding FIG. 2A or by any other conventional SOI process. However, in this embodiment, the dielectric layer may not be implanted as deep as the previous embodiment. The depth of the oxygen implant is conducted such that its depth leaves the desired amount of an upper portion 325 of the microelectronics substrate 315 available from which a bonding zone and the biasing region can later be formed. An anneal like the one mentioned above is conducted to form the first dielectric layer 320 within the microelectronics substrate 315. In an exemplary embodiment, the upper portion 325 is appropriately doped to form a biasing region 330. Additionally, the upper surface of the upper portion 325 may be subjected to an optional oxidation process to form a first bonding surface 335 to which the second microelectronics substrate 310 can be bonded, as discussed below.

The upper surface of the microelectronics substrate 310 is oxidized in a conventional manner to form a second bonding surface 340, as shown in FIG. 3B

The bonding surfaces of the active wafer 310 and the support wafer 315 are brought into contact with each other and are bonded together to form the substrate structure 345 shown in FIG. 3C. While this process is known to those skilled in the art, the following is set forth to generally describe exemplary processes that might be used to form the substrate structure 345.

The active wafer 310 is bonded to the support wafer 315. In most cases both active and support wafers 310, 315 have been oxidized, although some processes do not require the upper surface of the support wafer 315 to be oxidized. The bonded pair is annealed to increase bond strength. Processing differs depending on the techniques employed, but in all cases the active wafer 310 is reduced to the desired thickness after bonding. Several alternatives are possible to perform thinning, including plasma assisted chemical etching, bond and selective etch of porous silicon and implant-enhanced wafer splitting.

SmartCut® Technology from SOITEC is one variant of the bonded technique. Here, the wafer to be used for the active wafer 310 is implanted with hydrogen (protons) at approximately 1 um depth. Annealing creates a stress fracture. The active and support wafers 310, 315 are bonded, and the active wafer 310 is split along the stress fracture to generate a Unibond® wafer. The unused portion of the active wafer 310 can be reused (either as the support wafer 315 or active wafer 310), resulting in a cost saving over the traditional ground-back method (described above). The bonded combination is the SOI wafer. It is annealed and polished in readiness for use.

Eltran (Epitaxial Layer TRANsfer) is another method of creating SOI wafers. This process uses porous silicon to obtain a uniform SOI thickness. A region of about 12 um of porous silicon is formed by anodizing the surface of a boron-doped silicon wafer. An epitaxial silicon layer is grown on the porous silicon. The layer is bonded to the oxidized substrate wafer. The porous silicon is split from the epitaxial material, using a water jet, and results in a re-usable split wafer. The porous silicon remaining on the epitaxial silicon is selectively etched away. The quality of epitaxial silicon grown on porous silicon is poor due to stacking faults. However, stacking faults can be significantly reduced with a pre-bake in hydrogen before the epitaxy process. The material can be produced with an active layer thickness range between 50 nm and 5 μm, although the standard thickness ranges between 100 nm and 200 nm. The oxide thickness range available is also of the order of the same range. Surface roughness is comparable to bulk.

Nanocleave is an atomic layer cleaving process for bonded SOI, with a local surface roughness of less than the lattice constant of silicon (0.54 nM). This SOI fabrication process is based on forming a cleave plane on an active wafer, using ion implantation. A bonded wafer pair is created with the active wafer 310. The bond strength of the donor-handle interface is higher than the cleave plane. The cleaving is done at room temperature using the force of a nitrogen jet.

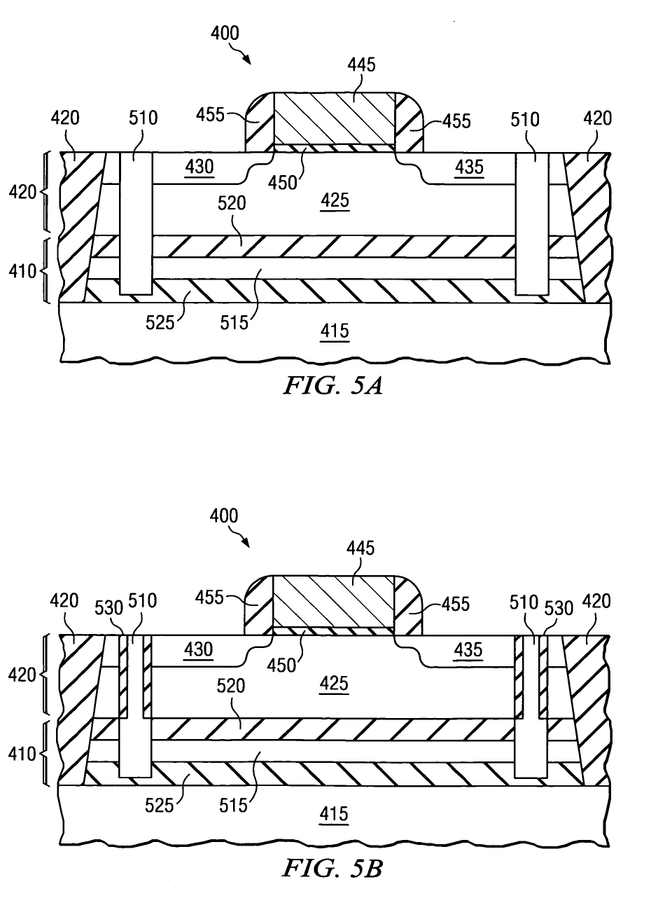

Referring now to FIG. 4, there is illustrated a partial section view of a microelectronic device 400 following the formation of a SOI region 410 in a microelectronics substrate 415, as described above, and after the conventional formation of trench isolation regions 420 and an active region 425 that comprises a well 430 and source and drains 435 and 440, respectively. Also shown are a conventionally formed transistor gate 445, gate oxide 450, and oxide spacers 455.

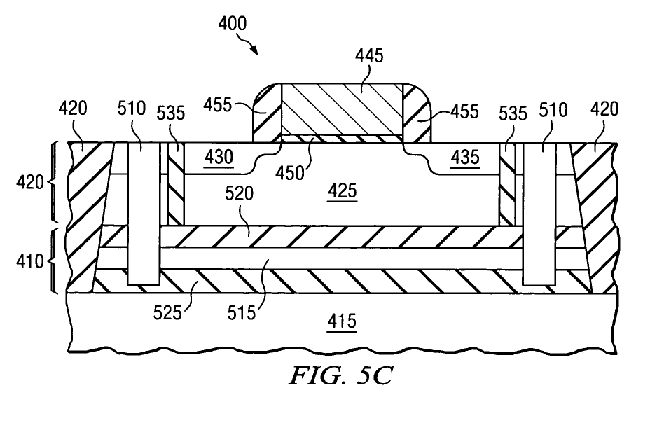

Turning next to FIG. 5A, illustrated is the microelectronics device 400 of FIG. 4 after the formation of contact openings 510. Conventional masking and etching processes can be used to form the contact openings 510. As seen in this embodiment, the contact openings extend into the SIO region 410 and intersect biasing layer 515 and first and second dielectric layers 520 and 525, respectively. Because of the first and second dielectric layers 520 and 525, the biasing layer 515 is electrically isolated from the active region 420 and bulk substrate 415.

Referring next to FIG. 5B, illustrated is the microelectronics device 500 of FIG. 5A after the formation of isolation regions 530 within the contact openings 510. As seen in the illustrated embodiment, the isolation region 530 covers the entire active region 420. The purpose of this is to further isolate the biasing layer 515 from the active region and prevent shorting therebetween, when a conductive material is deposited within the contact openings 510. Conventional deposition and etching processes can be used to form the isolation region 530. For example, an isolation liner can be formed on the interior side walls of the contact opening 510 and then the portion below the active region 420 can be removed. Alternatively, as shown in FIG. 5C, a separate isolation trench 535 can be formed through the active region and filled with a dielectric material using conventional lithographic processes.

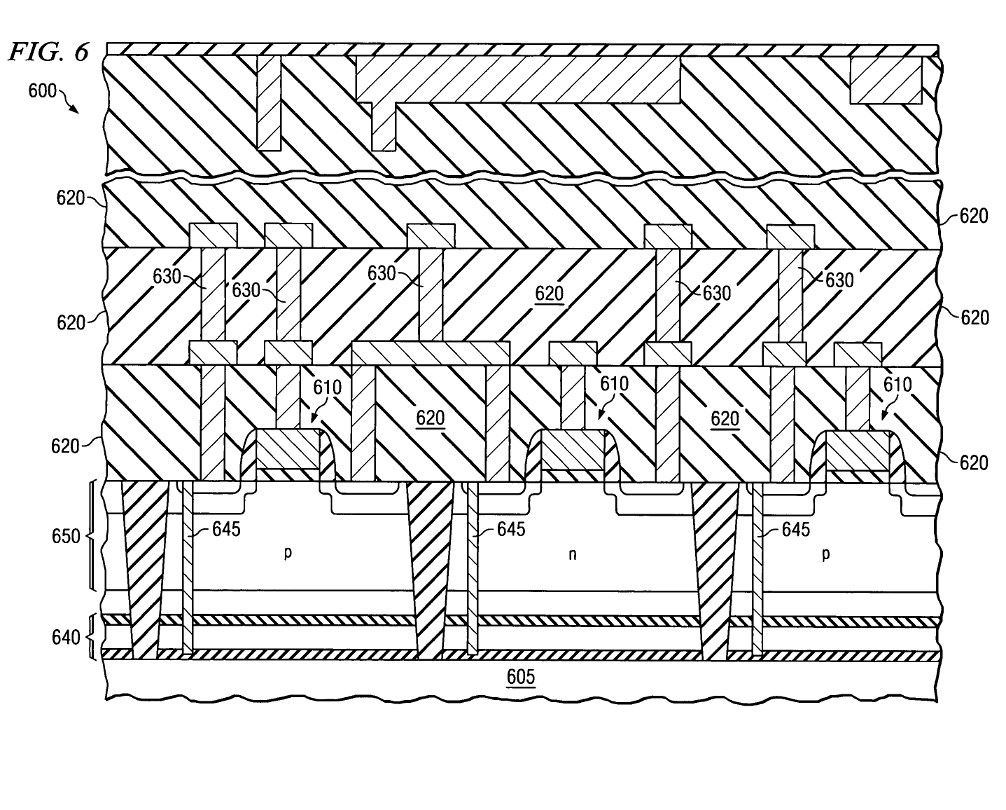

Turning now to FIG. 6, there is illustrated a schematic sectional view of an integrated circuit (IC) 600 that can be manufactured in accordance with the principles of the present invention. The IC 600 is formed on a doped substrate 605, such as a bulk silicon wafer, and includes devices 610, such as the transistor shown above in FIG. 1, to form CMOS devices, BiCMOS devices, Bipolar devices, as well as capacitors or other types of devices. The IC 600 may further include passive devices, such as inductors or resistors, or it may also include optical devices or optoelectronic devices, which are not shown here. Those skilled in the art are familiar with these various types of devices and their manufacture. In the particular embodiment illustrated in FIG. 6, the IC 600 includes the devices 610 having dielectric layers 620 located thereover. Additionally, interconnect structures 630 are located within the dielectric layers 620 to interconnect the various devices 610, thus, forming the operational integrated circuit 600. The IC 600 also includes the SIO region 640 as discussed and that can be electrically contacted by way of the contact plugs 645 that are also discussed above. The isolation regions that isolate the contact plugs 645 from the active region 650 are not shown due to scale, but are included as also discussed above. Also, for brevity, the SOI region 640 and contact plugs 645 are shown electrically associated with only one transistor device 610, however, as explained above; these structures may also be associated with any number of transistor devices.

Although the present invention has been described in detail, one who is of ordinary skill in the art should understand that they can make various changes, substitutions, and alterations herein without departing from the scope of the invention.

What is claimed is:

1. A method of fabricating a microelectronics device, comprising:
forming a silicon on insulator (SOI) region within a microelectronics substrate, the SOI region comprising a first dielectric layer located over the microelectronics substrate, a biasing layer located over the first dielectric layer and a second dielectric layer located over the biasing layer;
forming an active region over the SOI region; and
locating a contact plug through the active region and within the SOI region, the contact plug electrically contacting the biasing layer of the SOI region and being electrically isolated from the active region.

2. The method as recited in claim 1, wherein forming the SOI region comprises implanting the first and second dielectric layers within the microelectronics substrate.

3. The method as recited in claim 2, wherein the biasing layer is doped silicon and implanting comprises implanting oxygen into the microelectronics substrate and annealing the oxygen to form the respective first and second dielectric layers, wherein the first and second dielectric layers and the biasing layer each have a thickness ranging from about 0.5 microns to about 1 micron.

4. The method as recited in claim 1, wherein locating comprises;
forming an opening through the active region and into the SOI region;
placing a dielectric liner within the opening to isolate the active region; and
depositing a conductive metal within the opening.

5. The method as recited in claim 1, wherein forming the SOI region comprises;
implanting the first dielectric layer into a first doped bulk microelectronics substrate to a predetermined depth such that the first dielectric layer separates the biasing silicon layer from the first doped bulk microelectronics substrate;
forming the second dielectric layer on a surface of a second doped bulk microelectronics substrate; and
placing the second doped bulk microelectronics substrate onto the biasing layer, to thereby form the SOI region within the microelectronics substrate.

6. The method as recited in claim 1, the active region is doped silicon and the method further comprises;
forming a transistor gate over the active region, and
forming the active region comprises forming source and drain regions within a well region of the active region and adjacent the transistor gate.

7. The method as recited in claim 1, wherein the microelectronics substrate and the active region are doped with a first type of dopant and the biasing layer is doped with a second type of dopant opposite to the first type of dopant.

8. The method as recited in claim 1, wherein the microelectronics substrate and the active region are silicon and the first type of dopant is a p-type dopant and the second type of dopant is an n-type of dopant.

9. The method as recited in claim 1, wherein the contact plug is electrically isolated from the active region by an isolation trench.

10. A method of fabricating an integrated circuit, comprising:
forming a silicon on insulator (SOI) region within at least a portion of a microelectronics substrate, the SOI region comprising a first dielectric layer located over the microelectronics substrate, a biasing layer located over the first dielectric layer and a second dielectric layer located over the biasing layer;
forming an active region over the SOI region;
creating transistors over the active region, each of the transistors being electrically isolated from the active region by a gate oxide;
locating biasing contact plugs through the active region and within the SOI region adjacent at least a portion of the transistors, the contact plug electrically contacting the biasing layer of the SOI region and being electrically isolated from the active region;
depositing dielectric layers over the transistors; and
forming interconnects within the dielectric layers to interconnect the transistors and the biasing contact plugs to form an operative integrated circuit.

11. The method as recited in claim 10, wherein forming the SOI region comprises implanting the first and second dielectric layers within the microelectronics substrate.

12. The method as recited in claim 11, wherein the biasing layer is doped silicon and implanting comprises implanting oxygen into the microelectronics substrate and annealing the oxygen to form the respective first and second dielectric layers and wherein the first and second dielectric layers and the biasing layer each have a thickness ranging from about 0.5 microns to about 1 micron.

13. The method as recited in claim 10, wherein locating comprises;
forming an opening through the active region and into the SOI region;
placing a dielectric liner within the opening to isolate the active region; and
depositing a conductive metal within the opening.

14. The method as recited in claim 10, wherein forming the SOI region comprises;
implanting the first dielectric layer into a first doped bulk microelectronics substrate to a predetermined depth such that the first dielectric layer separates the biasing silicon layer from the first doped bulk microelectronics substrate;
forming the second dielectric layer on a surface of a second doped bulk microelectronics substrate; and
placing the second doped bulk microelectronics substrate onto the biasing layer, to thereby form the SOI region within the microelectronics substrate.

15. The method as recited in claim 10, the active region is doped silicon and the method further comprises forming a transistor gate over the active region, and forming the active region comprises forming source and drain regions within a well region of the active region and adjacent the transistor gate.

16. The method as recited in claim 10, wherein the microelectronics substrate and the active region are doped with a first type of dopant and the biasing layer is doped with a second type of dopant opposite to the first type of dopant.

17. The method as recited in claim 10, wherein the microelectronics substrate and the active region are silicon and the first type of dopant is a p-type dopant and the second type of dopant is an n-type of dopant.

18. The method as recited in claim 10 further including forming an isolation trench in the active region to electrically isolate the contact plug from the active region.

19. A microelectronics device, comprising:
a silicon on insulator (SOI) region located within a microelectronics substrate, the SOI region comprising a first dielectric layer located over the microelectronics substrate, a biasing layer located over the first dielectric layer and a second dielectric layer located over the biasing layer;
an active region located over the SOI region; and
a contact plug located through the active region and within the SOI region, the contact plug electrically contacting the biasing layer of the SOI region and being electrically isolated from the active region.

20. The microelectronics device as recited in claim 19, wherein the SOI region comprises first and second implanted dielectric layers.

21. The microelectronics device as recited in claim 20, wherein the biasing layer is doped silicon and the first and second dielectric layers are silicon dioxide, and wherein the first and second dielectric layers and the biasing layer each have a thickness ranging from about 0.5 microns to about 1 micron.

22. The microelectronics device as recited in claim 19, wherein the contact plug comprises;
a conductive metal located within an opening that is located through the active region and into the SOI region; and
a dielectric located within the opening to isolate the active region from the conductive metal.

23. The microelectronics device as recited in claim 19, wherein the SOI region comprises;
a first dielectric layer located in a first doped bulk microelectronics substrate to a predetermined depth such that the first dielectric layer separates the biasing layer from the first doped bulk microelectronics substrate;
a second dielectric layer on a surface of a second doped bulk microelectronics substrate; and
placing the second doped bulk microelectronics substrate onto the biasing layer, to thereby form the SOI region within the microelectronics substrate.

24. The microelectronics device as recited in claim 19, wherein the microelectronics device is an integrated circuit that comprises a plurality of contact plugs and wherein the active region is doped silicon and the microelectronics device further comprises;
transistors located over and electrically isolated from the active region by a gate oxide, a contact plug being located adjacent at least a portion of the transistors;
source and drain regions located within a well region of the active region and adjacent the transistor gate, wherein the SOI region is located under at least a portion of the transistors;
interlevel dielectric layers located over the transistors; and
interconnects formed within the dielectric layers that interconnect the transistors and contact plugs to form an operative integrated circuit.

25. The method as recited in claim 19, wherein the microelectronics substrate and the active region are doped with a first type of dopant and the biasing layer is doped with a second type of dopant opposite to the first type of dopant.

26. The method as recited in claim 19, wherein the microelectronics substrate and the active region are silicon and the first type of dopant is a p-type dopant and the second type of dopant is an n-type of dopant.
